(19) United States
(12) Patent Application Publication
(10) Pub. No.: US 2025/0171867 A1
(43) Pub. Date: May 29, 2025

(54) MICROWAVE ANNEALING PROCESS AND MICROWAVE ANNEALING DEVICE

(71) Applicant: Industrial Technology Research Institute, Hsinchu (TW)

(72) Inventors: Kun-Ping Huang, Miaoli County (TW); Fan-Yun Chiu, Pingtung County (TW)

(73) Assignee: Industrial Technology Research Institute, Hsinchu (TW)

(21) Appl. No.: 18/953,091

(22) Filed: Nov. 20, 2024

Related U.S. Application Data
(60) Provisional application No. 63/602,373, filed on Nov. 23, 2023.

(30) Foreign Application Priority Data
Aug. 28, 2024 (TW) 113132314

(51) Int. Cl. C21D 1/26; C21D 1/34; H05B 6/80

(52) U.S. Cl. CPC C21D 1/26; C21D 1/34; H05B 6/80

(57) ABSTRACT

A microwave annealing process and a microwave annealing device are provided. The microwave annealing process includes using a microwave annealing device. The microwave annealing device includes a chamber, a stage and at least one microwave transmitter. The chamber has an accommodation space. The stage is disposed in the accommodation space. The stage has a plane to carry at least one annealing object. The annealing object includes a magnetic tunnel junction element. The at least one microwave transmitter is disposed outside the chamber to generate microwaves. A dielectric constant of a material of the stage is greater than 3. An electric field direction of the microwave output by the at least one microwave transmitter is perpendicular to the plane of the stage in the chamber.

### CROSS-REFERENCE TO RELATED APPLICATION

This application claims the priority benefit of U.S. Provisional Application No. 63/602,373, filed on Nov. 23, 2023 and Taiwan Application No. 113132314, filed on Aug. 28, 2024. The entirety of each of the above-mentioned patent applications is hereby incorporated by reference herein and made a part of this specification.

### TECHNICAL FIELD

The technical field relates to an annealing process and an annealing device, and particularly relates to a microwave annealing process and a microwave annealing device.

### BACKGROUND

In semiconductor manufacturing processes, wafer annealing is a necessary procedure after ion implantation. For example, magnetoresistive random access memory (MRAM) requires magnetic annealing to form or enhance perpendicular anisotropy. However, current magnetic annealing requires an externally applied magnetic field of 0.3 tesla to 1 tesla, and is performed under conditions of temperature ranging from 250° C. to 400° C. and high vacuum (for example, pressure below 1×10⁻⁶ torr). The high-temperature environment may damage the multilayer film interface of the magnetic tunnel junction (MTJ) in the MRAM, thereby affecting the performance of the MRAM including the same.

### SUMMARY

One of exemplary embodiments comprises a microwave annealing process including using a microwave annealing device. The microwave annealing device includes a chamber, a stage and at least one microwave transmitter. The chamber has an accommodation space. The stage is disposed in the accommodation space. The stage has a plane to carry at least one annealing object. The annealing object includes a magnetic tunnel junction element. The at least one microwave transmitter is disposed outside the chamber to generate microwaves. A dielectric constant of a material of the stage is greater than 3. An electric field direction of the microwave output by the at least one microwave transmitter is perpendicular to the plane of the stage in the chamber.

One of exemplary embodiments comprises a microwave annealing device including a chamber, a stage and at least one microwave transmitter. The chamber has an accommodation space. The stage is disposed in the accommodation space. The stage has a plane to carry at least one annealing object. The at least one microwave transmitter is disposed outside the chamber to generate microwaves. A dielectric constant of a material of the stage is greater than 3. An electric field direction of the microwave output by the at least one microwave transmitter is perpendicular to the plane of the stage in the chamber.

Based on the above, the microwave annealing device used in the microwave annealing process of the disclosure includes at least one microwave transmitter for generating microwaves, and the electric field direction of the microwaves output by the microwave transmitter is perpendicular to the plane of the stage in the chamber.

### BRIEF DESCRIPTION OF THE DRAWINGS

FIG. 1 is a schematic diagram of a microwave annealing device according to an exemplary embodiment.

FIG. 2 is a top view of a chamber of a microwave annealing device according to an exemplary embodiment.

### DETAILED DESCRIPTION OF DISCLOSED EMBODIMENTS

The following will comprehensively describe exemplary implementations of the disclosure with reference to the figures, but the disclosure may also be implemented in many different forms and should not be construed as limited to the implementations described herein. In the figures, the sizes and thicknesses of components, parts, and layers may not be drawn to actual scale for clarity. Directional terms mentioned in this document, such as “upper”, “lower”, “front”, “back”, etc., are only referenced to the orientation of the accompanying figures. Therefore, the directional terms used are for explaining and understanding this application, and not for limiting this application. Additionally, in the specification, unless explicitly described otherwise, the word “include” will be understood to mean including the stated elements, but not excluding any other elements. For ease of understanding, the same elements in the following description will be explained using the same symbols.

The implementation details provided in the implementations are for illustrative purposes and are not intended to limit the scope of protection of the disclosure. Any expert in the relevant technical field may modify or vary these implementation details according to the needs of actual implementation. Moreover, descriptions of well-known devices, methods, and materials may be omitted to avoid obscuring the description of the various principles of the disclosure.

Ranges in this document may be expressed from “about” one specific value to “about” another specific value, or may be directly expressed as one specific value and/or to another specific value. When expressing said range, another implementation includes from that one specific value and/or to another specific value. Similarly, when values are expressed as approximations by using the antecedent “about”, it will be understood that the specific value forms another implementation. It will be further understood that the endpoints of each range are apparently related or unrelated to another endpoint.

In this document, non-limiting terms (such as: may, can, for example, or other similar expressions) are for non-essential or optional implementation, inclusion, addition, or presence.

Unless otherwise defined, all terms used herein (including technical and scientific terms) have the same meanings as commonly understood by experts in the technical field to which the disclosure pertains. It will also be understood that terms, such as those defined in commonly used dictionaries, should be interpreted as having meanings consistent with their meaning in the context of the relevant art and should not be interpreted in an idealized or overly formal sense unless explicitly so defined herein.

### <Microwave Annealing Device>

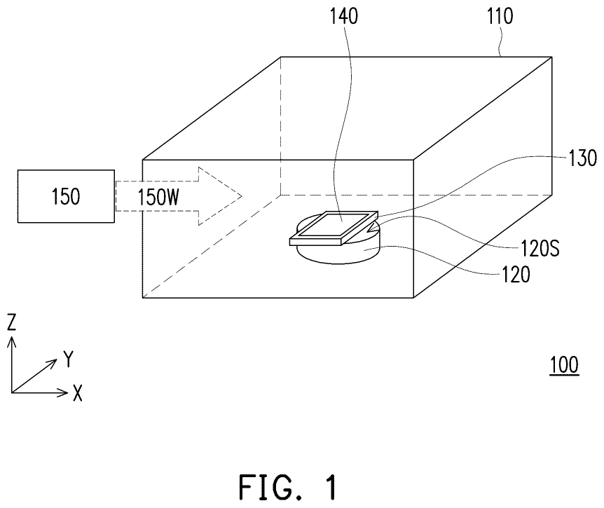

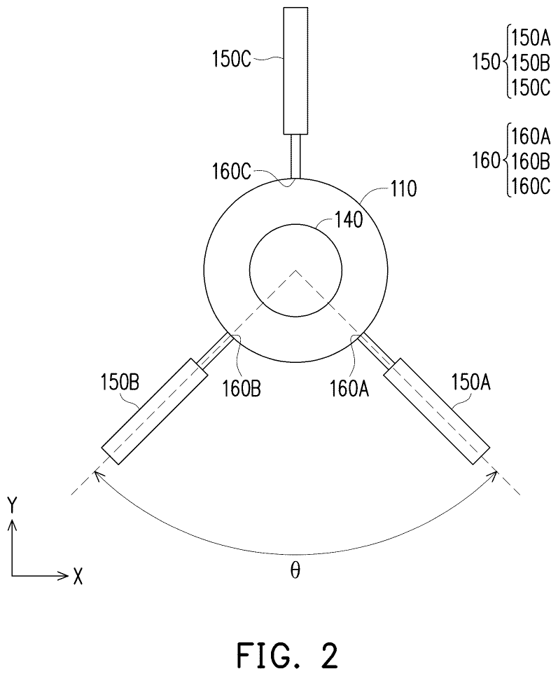

One of exemplary embodiments comprises a microwave annealing process including using a microwave annealing device provided by an exemplary embodiment of the disclosure. FIG. 1 is a schematic diagram of a microwave annealing device according to an exemplary embodiment. FIG. 2 is a top view of a chamber of a microwave annealing device according to an exemplary embodiment. Referring to FIG. 1 and FIG. 2, the microwave annealing device 100 includes a chamber 110, a stage 120, an annealing object 140, and a microwave transmitter 150. In this embodiment, the microwave annealing device 100 may further include a high dielectric constant object 130, an input port 160, or other elements known to experts in this field, which will not be described in detail here. In this embodiment, the microwave annealing device 100 may not require to dispose a magnetic field supplier, and may not require to dispose a vacuum pumping device.

The chamber 110 is a hollow chamber. The chamber 110 has an accommodation space and disposes a stage to carry the annealing object. The chamber may have multiple input ports 160 for inputting microwaves for annealing. The shape of the chamber 110 is not particularly limited and suitable shape may be selected according to needs. For example, the shape of the chamber 110 may be a cuboid (as shown in FIG. 1) or a cylinder (as shown in FIG. 2), but is not limited thereto. The chamber 110 may be enclosed or non-enclosed, and the suitable enclosure condition may be selected according to needs.

The stage 120 is disposed in the accommodation space of the chamber 110. The stage 120 has a plane 120S to carry at least one annealing object 140. In this embodiment, the stage 120 may be a fixed stage. During the microwave annealing process, the position of the stage 120 may remain fixed, without rotating or elevating the stage height as the microwave annealing process progresses. The dielectric constant of the material of the stage 120 may be greater than 3, for example, may be 3 to 12, and preferably 8 to 12. The material of the stage 120 may include quartz, silicon carbide, aluminum oxide, silicon, or other suitable materials.

The annealing object 140 is disposed on the plane 120S of the stage 120. The annealing object 140 includes a magnetic tunnel junction element. The magnetic tunnel junction element may be a unit memory element of magnetoresistive random access memory (MRAM), which is also the most crucial part of the entire MRAM. The magnetic tunnel junction element may include two layers of ferromagnetic metal and an extremely thin potential barrier layer (PBL) therebetween.

In this embodiment, the microwave annealing device 100 may further include a high dielectric constant object 130. The high dielectric constant object 130 may be provided at least one of above and below the annealing object 140. For example, the high dielectric constant object 130 may be provided below the annealing object 140, that is, provided between the annealing object 140 and the stage 120 (as shown in FIG. 1). The dielectric constant of the material of the high dielectric constant object 130 may be greater than 3, for example, may be 3 to 15, and preferably 8 to 15; the dielectric loss factor thereof may be 0.0001 or more. The material of the high dielectric constant object 130 may include silicon carbide (SiC), aluminum oxide (Al₂O₃), silicon (Si), or other suitable materials. When the microwave annealing device 100 further includes the high dielectric constant object 130 provided at least one of above and below the annealing object 140, it may enhance the strength of the electromagnetic field generated by the microwave, thereby reducing the microwave power provided by the microwave transmitter, decreasing the total annealing time, and/or lowering the annealing temperature.

The at least one microwave transmitter 150 is disposed outside the chamber 110 (for example, FIG. 1 only shows one microwave transmitter 150). The microwave transmitter 150 may be at the same height as the annealing object 140, that is, the microwave transmitter 150 and the annealing object 140 are on the same level (coplanar). The microwave transmitter 150 is connected to a controller (not shown) to receive commands issued by the controller, thereby controlling the frequency, phase, power, and amplitude of the microwave output by the microwave transmitter 150. The frequency of the microwave may be 300 MHz to 300 GHz, preferably 915 MHz to 5.8 GHz. The microwave transmitter includes a variable frequency microwave supplier, so it may generate microwaves of suitable frequency according to needs.

The electric field of the microwave 150W output by the microwave transmitter 150 is perpendicular to the plane 120S of the stage 120 inside the chamber 110. The direction perpendicular to the plane 120S of the stage 120 is direction Z. For example, after the microwave 150W output by the microwave transmitter 150 is transmitted to a directional coupler (not shown), it is input into the chamber 110 through the input port 160. The electric field direction of the microwave is required to be perpendicular to the plane 120S of the stage 120 to perform the annealing process on the annealing object 140 in the chamber 110. The electric field direction of the microwave in the chamber 110 is substantially the same as the direction Z perpendicular to the plane 120S of the stage 120.

In this embodiment, at least one microwave transmitter 150 may be two or more microwave transmitters. For example, multiple microwave transmitters 150A, 150B, 150C may be disposed outside the chamber 110, outputting microwaves respectively, which are then input to the input ports 160A, 160B, 160C of the chamber 110 through input directional couplers (not shown) (as shown in FIG. 2). For ease of explanation and simplification of the diagram, only three microwave transmitters 150A, 150B, 150C are shown here, but the number of microwave transmitters is not limited thereto. In other embodiments, the suitable number of microwave transmitters may be selected according to needs. The greater the number of microwave transmitters, the easier it is to generate uniform microwave heating modes for performing the annealing process. From the perspective of power supply, the number of microwave transmitters is preferably a multiple of 3, but is not limited thereto. The microwave transmitters 150A, 150B, 150C may be connected to the controller (not shown) respectively to receive commands issued by the controller separately; the controller may make the microwave transmitters 150A, 150B, 150C output the same/different microwave frequencies, phases, powers, and amplitudes respectively.

As shown in FIG. 2, when the number of microwave transmitters is two or more, the microwave transmitters 150A, 150B, 150C and their corresponding input ports 160A, 160B, 160C may be sequentially surrounded the outer peripheral sidewall of the chamber 110. The microwave transmitters 150A, 150B, 150C and their corresponding input ports 160A, 160B, 160C may be distributed at any position on the outer peripheral sidewall of the chamber 110. The microwave transmitters 150A, 150B, 150C and their corresponding input ports 160A, 160B, 160C may be surrounded the chamber 110 with equal or unequal angular distribution, preferably with equal angular distribution. For example, when the number of microwave transmitters is three, the angle θ between adjacent microwave transmitters may be 120 degrees, which is an equal angular distribution. When the number of microwave transmitters is six, the angle between adjacent microwave transmitters may be 60 degrees, which is an equal angular distribution. The number of input ports may be the same as the number of microwave transmitters, or the number of input ports may be greater than or equal to the number of microwave transmitters.

A part of or all of the microwave transmitters 150A, 150B, 150C may be located at the same height. A part of or all of the microwave transmitters 150A, 150B, 150C may be at the same height as the annealing object 140, preferably all of the microwave transmitters 150A, 150B, 150C are at the same height as the annealing object 140, i.e., all of the microwave transmitters and the annealing object are on the same level (coplanar). In other embodiments, multiple microwave transmitters may be positioned at different heights according to needs. For example, when the number of microwave transmitters is six, the six microwave transmitters may be positioned on the same level, i.e., the six microwave transmitters are coplanar; or three microwave transmitters may be disposed on the same level, and the other three microwave transmitters may be disposed on another level, to arrange the microwave transmitters in two layers. However, the disclosure is not limited thereto, and a suitable arrangement of multiple microwave transmitters may be selected according to needs.

The microwave annealing process is performed by means of the vertical electric field of the microwave output from the microwave transmitter 150 in the chamber 110 of the microwave annealing device 100, to perform the anneal process on the annealing object 140. The steps of the microwave annealing process may be similar to the annealing process steps known to experts in the field. Therefore, it is not described in detail herein.

In this embodiment, by means of using the vertical electric field in the chamber 110 to perform annealing, in the annealing process, the annealing temperature may be less than 150° C., the pressure may be normal pressure, and the total annealing time may be less than 12 minutes; preferably, the annealing temperature may be less than 120° C., the pressure may be normal pressure, and the total annealing time may be less than 10 minutes. When a high dielectric constant object is provided at least one of above and below the annealing object, in the annealing process, the annealing temperature may be less than 200° C., the pressure may be normal pressure, and the total annealing time may be less than 10 minutes; preferably, the annealing temperature may be less than 180° C., the pressure may be normal pressure, and the total annealing time may be less than 8 minutes.

### <Microwave Annealing Device>

One of exemplary embodiments comprises an aforementioned microwave annealing device.

### EXAMPLES

The annealing object is placed on the plane of the stage in the microwave annealing device to perform the microwave annealing process, wherein the stage is a quartz column (with a thickness of 11.05 mm in the Z direction), and the annealing object includes a magnetic tunnel junction (MTJ) element and a high dielectric constant material. During the microwave annealing, the coercivity (Hc) and tunnel magnetoresistance (TMR) of the MTJ element are measured. When the coercivity (Hc) is greater than 30 Oe and the tunnel magnetoresistance (TMR) is greater than 75%, the annealing process is terminated, and the results are shown in Table 1. The main difference between each example is: changing the material of the high dielectric constant object (as shown in Table 1).

TABLE 1

| | | | Comparative |
|---|---|---|---|
| | | | Example 1 |
| | | | (Conventional |
| | Examples | | annealing |
| | 1 | 2 | process) |
| External magnetic field | 0 | 0 | 1 |
| (tesla) | | | |
| Material of high | Si (dielectric | SiC (dielectric | None |
| dielectric constant | constant of | constant of | |
| object | approximately | approximately | |
| | 11) | 9) | |
| Microwave power (kW) | 3 | 3 | None |
| Annealing temperature | 80 | 78 | >300 |
| (° C.) | | | |
| Pressure (torr) | 760 | 760 | 1 × 10⁻⁶ |
| Total annealing time | 5 | 1 | 240 |
| (minutes) | | | |
| Hc (Oe) | 30.56 | 46.74 | 30 |
| TMR (%) | 85.68 | 85.73 | 75 |

As may be seen from Table 1, when the microwave output by the microwave transmitter in the microwave annealing device is perpendicular to the plane of the stage in the chamber, the microwave annealing process using the device may complete the annealing process in a short time without applying an external magnetic field, under conditions where the temperature is less than 150° C. (even less than 100° C.) and the pressure is about 760 torr (i.e., normal pressure) (Examples 1-2). In contrast, the conventional annealing process requires applying an external magnetic field and completes the annealing process over a long time under high temperature and high vacuum conditions (Comparative Example 1), that is, requires higher costs and lower productivity.

Based on the above, the exemplary embodiments provide a microwave annealing device used in the microwave annealing process including at least one microwave transmitter for generating microwaves, and when the microwave output by the microwave transmitter is perpendicular to the plane of the stage in the chamber, it may enable the microwave annealing process using the vertical electric field generated by the microwave annealing device to be carried out under conditions without applying an external magnetic field, at a temperature less than 150° C. and under normal pressure, thereby reducing the cost and increasing productivity of the annealing process, thus having good applicability.

What is claimed is:

1. A microwave annealing process, comprising:
using a microwave annealing device, the microwave annealing device comprising:
a chamber, having an accommodation space;
a stage, disposed in the accommodation space, the stage having a plane to carry at least one annealing object, the annealing object comprising a magnetic tunnel junction element; and
at least one microwave transmitter, disposed outside the chamber to generate microwaves,
wherein a dielectric constant of a material of the stage is greater than 3, and an electric field direction of the microwave output by the at least one microwave transmitter is perpendicular to the plane of the stage in the chamber.

2. The microwave annealing process of claim 1, wherein an annealing temperature is less than 150° C.

3. The microwave annealing process of claim 1, further comprising a high dielectric constant object, provided at least one of above and below the annealing object.

4. The microwave annealing process of claim 3, wherein a dielectric constant of a material of the high dielectric constant object is greater than 3.

5. The microwave annealing process of claim 1, wherein the at least one microwave transmitter is two or more microwave transmitters, the two or more microwave transmitters surrounding the chamber and distributed at equal angle.

6. A microwave annealing device, comprising:
a chamber, having an accommodation space;
a stage, disposed in the accommodation space, the stage having a plane to carry at least one annealing object; and
at least one microwave transmitter, disposed outside the chamber to generate microwaves,
wherein a dielectric constant of a material of the stage is greater than 3, and an electric field direction of the microwave output by the at least one microwave transmitter is perpendicular to the plane of the stage in the chamber.

7. The microwave annealing device of claim 6, wherein the annealing object comprising a magnetic tunnel junction element.

8. The microwave annealing device of claim 6, further comprising a high dielectric constant object, provided at least one of above and below the annealing object.

9. The microwave annealing device of claim 8, wherein a dielectric constant of a material of the high dielectric constant object is greater than 3.

10. The microwave annealing device of claim 6, wherein the at least one microwave transmitter is two or more microwave transmitters, the two or more microwave transmitters surrounding the chamber and distributed at equal angle.
